(19) United States
(12) Patent Application Publication
(10) Pub. No.: US 2011/0039747 A1
(43) Pub. Date: Feb. 17, 2011

(54) COMPOSITION AND METHOD FOR REMOVING ION-IMPLANTED PHOTORESIST

(75) Inventors: Renjie Zhou, Plainsboro, NJ (US); Emanuel Cooper, Scarsdale, NY (US); Michael B. Korzenski, Danbury, CT (US); Ping Jiang, Danbury, CT (US)

Correspondence Address: MOORE & VAN ALLEN PLLC, P.O. BOX 13706, Research Triangle Park, NC, 27709, US

(73) Assignee: ADVANCED TECHNOLOGY MATERIALS, INC., Danbury, CT (US)

(21) Appl. No.: 12/673,860

(22) PCT Filed: Aug. 20, 2008
(86) PCT No.: PCT/US08/73650

§ 371 Date: Jun. 30, 2010

Related U.S. Application Data
(60) Provisional application No. 60/965,456, filed on Aug. 20, 2007.

(51) Int. Cl. G03F 7/42

(52) U.S. Cl. 510/176

(57) ABSTRACT

A method and mineral acid-containing compositions for removing bulk and/or hardened photoresist material from microelectronic devices have been developed. The mineral acid-containing composition includes at least one mineral acid, at least one sulfur-containing oxidizing agent, and optionally at least one metal ion-containing catalyst. The mineral acid-containing compositions effectively remove the hardened photoresist material while not damaging the underlying silicon-containing layer(s).

### FIELD

The present invention relates generally to mineral acid-containing compositions useful for the removal of bulk and hardened photoresist from the surface of microelectronic devices, and methods of using said compositions for removal of same.

### DESCRIPTION OF THE RELATED ART

As semiconductor devices have become more integrated and miniaturized, ion implantation has been extensively employed during front-end-of-line (FEOL) processing to accurately control impurity distributions in the microelectronic device and to add dopant atoms, e.g., As, B and P, to the exposed device layers. The concentration and depth of the dopant impurity is controlled by varying the dose of the dopant, the acceleration energy, and the ion current. Prior to subsequent processing, the ion-implanted photoresist layer must be removed. Various processes have been used in the past for the removal of said hardened photoresist including, but not limited to, wet chemical etching processes, e.g., in a mixed solution of sulphuric acid and hydrogen peroxide (i.e., a Piranha solution), and dry plasma etching processes, e.g., in an oxygen plasma ashing process.

Unfortunately, when high doses of ions (e.g., doses greater than about 1×10¹⁵ atoms cm⁻²), at low (5 keV), medium (10 keV) and high (20 keV) implant energy, are implanted in the desired layer, they are also implanted throughout the photoresist layer, particularly the exposed surface of the photoresist, which becomes physically and chemically rigid. The rigid ion-implanted photoresist layer, also referred to as the carbonized region or “crust,” has proven difficult to remove.

Presently, the removal of the ion-implanted photoresist and other contaminants is usually performed by a plasma etch method followed by a multi-step wet strip process, typically using aqueous-based etchant formulations to remove photoresist, post-etch residue, and other contaminants. Wet strip treatments in the art generally involve the use of strong acids, bases, solvents, and oxidizing agents. Disadvantageously, however, wet strip treatments also etch the underlying silicon-containing layers, such as the substrate and gate oxide, and/or increase the gate oxide thickness.

As the feature sizes continue to decrease, satisfying the aforementioned removal requirements becomes significantly more challenging using the aqueous-based etchant formulations of the prior art. Water has a high surface tension which limits or prevents access to the smaller image nodes with high aspect ratios, and therefore, removing the residues in the crevices or grooves becomes more difficult. In addition, aqueous-based etchant formulations often leave previously dissolved solutes behind in the trenches or vias upon evaporative drying, which inhibit conduction and reduce device yield. Furthermore, underlying porous low-k dielectric materials do not have sufficient mechanical strength to withstand the capillary stress of high surface tension liquids such as water, resulting in pattern collapse of the structures. Aqueous etchant formulations can also strongly alter important material properties of the low-k materials, including dielectric constant, mechanical strength, moisture uptake, coefficient of thermal expansion, and adhesion to different substrates.

Therefore, it would be a significant advance in the art to provide an improved composition that overcomes the deficiencies of the prior art relating to the removal of bulk and hardened photoresist from microelectronic devices. The improved composition shall effectively remove bulk and hardened photoresist in a one-step or multi-step process, without the need for a plasma etch step and without substantially over-etching the underlying silicon-containing layer(s).

### SUMMARY

The present invention relates generally to mineral acid-containing compositions useful for the removal of bulk and hardened photoresist from the surface of microelectronic devices, methods of making and methods of using said compositions for removal of same, and improved microelectronic devices made using the same. More specifically, a composition useful for the removal of high-dose ion implanted photoresist film and methods of using same are described. Advantageously, the compositions described herein are compatible with low-k dielectric materials on the microelectronic device.

In one aspect, a mineral acid-containing composition comprising at least one mineral acid and at least one sulfur-containing oxidizing agent is described, wherein the composition is suitable for removing bulk and/or hardened photoresist material from a microelectronic device having said photoresist material thereon.

In another aspect, a mineral acid-containing composition consisting essentially of at least one mineral acid and at least one sulfur-containing oxidizing agent is described, wherein the composition is suitable for removing bulk and/or hardened photoresist material from a microelectronic device having said photoresist material thereon.

In still another aspect, a mineral acid-containing composition consisting of at least one mineral acid and at least one sulfur-containing oxidizing agent is described, wherein the composition is suitable for removing bulk and/or hardened photoresist material from a microelectronic device having said photoresist material thereon.

In yet another aspect, a mineral acid-containing composition comprising at least one mineral acid, at least one sulfur-containing oxidizing agent, and at least one metal ion-containing catalyst is described, wherein the composition is suitable for removing bulk and/or hardened photoresist material from a microelectronic device having said photoresist material thereon.

Still another aspect relates to a mineral acid-containing composition consisting essentially of at least one mineral acid, at least one sulfur-containing oxidizing agent, and at least one metal ion-containing catalyst, wherein the composition is suitable for removing bulk and/or hardened photoresist material from a microelectronic device having said photoresist material thereon.

Another aspect relates to a mineral acid-containing composition consisting of at least one mineral acid, at least one sulfur-containing oxidizing agent, and at least one metal ion-containing catalyst, wherein the composition is suitable for removing bulk and/or hardened photoresist material from a microelectronic device having said photoresist material thereon.

Yet another aspect relates to a method of removing bulk and/or hardened photoresist material from a microelectronic device having said photoresist material thereon, said method comprising contacting the microelectronic device with a mineral acid-containing composition for sufficient time and under sufficient contacting conditions to at least partially remove said photoresist material from the microelectronic device, wherein the mineral acid-containing composition includes at least one mineral acid, at least one sulfur-containing oxidizing agent, and optionally at least one metal ion-containing catalyst.

In yet another aspect, a method of manufacturing a microelectronic device is described, said method comprising contacting the microelectronic device with a mineral acid-containing composition of the invention for sufficient time and under sufficient contacting conditions to at least partially remove bulk and/or hardened photoresist material from the microelectronic device having said photoresist material thereon, and optionally incorporating said cleaned microelectronic device into a product.

Yet another aspect relates to improved microelectronic devices, and products incorporating same, made using the methods described herein comprising removing bulk and/or hardened photoresist from the microelectronic device having said photoresist thereon, using the methods and/or compositions described herein, and optionally, incorporating the microelectronic device into a product.

Another aspect relates to an article of manufacture comprising a mineral acid-containing composition, a microelectronic device wafer, and bulk and/or hardened photoresist, wherein the composition comprises at least one mineral acid, at least one sulfur-containing oxidizing agent, and optionally at least one metal ion-containing catalyst.

Still another aspect relates to packaging a mineral acid-containing composition for shipping, mixing and delivery, wherein the mineral acid-containing composition includes at least one mineral acid, at least one sulfur-containing oxidizing agent, and optionally at least one metal ion-containing catalyst, said packaging comprising an external package comprising at least two internal containers or bladders, wherein a first internal container or bladder includes the at least one sulfur-containing oxidizing agent and a second internal container or bladder includes the at least one mineral acid and optionally at least one metal ion-containing catalyst, wherein the contents of the first and second internal containers or bladders may be mixed within the external package to form the mineral acid-containing composition. The formed mineral acid-containing composition may thereafter be delivered to a microelectronic device for sufficient time to remove bulk and/or hardened photoresist from the microelectronic device having said photoresist thereon.

Other aspects, features and advantages of the invention will be more fully apparent from the ensuing disclosure and appended claims.

### BRIEF DESCRIPTION OF THE DRAWINGS

FIGS. 1A and 1B are scanning electron micrographs of the control surface (FIG. 1A), and the photoresist including boron ions following cleaning using a mineral acid-containing composition described herein (FIG. 1B).

FIGS. 2A and 2B are scanning electron micrographs of the control surface (FIG. 2A), and the photoresist including arsenic ions following cleaning using a mineral acid-containing composition described herein (FIG. 2B).

### DETAILED DESCRIPTION, AND PREFERRED EMBODIMENTS THEREOF

The present invention is based generally on the discovery of mineral acid-containing compositions, specifically sulfuric acid-containing compositions, which are highly efficacious for the removal of bulk and hardened photoresist from the surface of microelectronic devices. More specifically, the mineral acid-containing compositions are particularly useful for the removal of high dose ion-implanted photoresist from the surface of a microelectronic device having same thereon.

For ease of reference, “microelectronic device” corresponds to semiconductor substrates, flat panel displays, phase change memory devices, solar panels and photovoltaics, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly.

“Bulk photoresist,” as used herein, corresponds to the photoresist on the microelectronic device surface, specifically adjacent and below the hardened photoresist crust.

“Hardened photoresist” as used herein includes, but is not limited to: photoresist that has been plasma etched, e.g., during back-end-of-line (BEOL) dual-damascene processing of integrated circuits; ion implanted, e.g., during front-end-of-line (FEOL) processing to implant dopant species in the appropriate layers of the semiconductor wafer; and/or any other methodology whereby a carbonized or highly cross-linked crust forms on the exposed surface of the bulk photoresist. Doping species include, but are not limited to, boron, arsenic, boron difluoride, indium, antimony, germanium, and/or phosphorous ions.

As used herein, “underlying silicon-containing” layer corresponds to the layer(s) immediately below the bulk and/or the hardened photoresist including, but not limited to: silicon; silicon oxide, including gate oxides (e.g., thermally or chemically grown SiO₂) and TEOS; silicon nitride; and low-k dielectric materials. As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

“Substantially devoid” and “devoid” is defined herein as less than 2 wt. %, preferably less than 1 wt. %, more preferably less than 0.5 wt. %, and most preferably less than 0.1 wt. %.

As defined herein, “substantially over-etching” corresponds to greater than about 10% removal, more preferably greater than about 5% removal, and most preferably greater than about 2% removal, of the adjacent underlying silicon-containing layer(s) following contact, according to the process described herein, of the mineral acid-containing compositions described herein with the microelectronic device having said underlying layer(s). In other words, most preferably no more than 2% of the underlying silicon-containing layer(s) are etched using the compositions described herein for the prescribed times at the prescribed temperatures.

As used herein, “about” is intended to correspond to ±5% of the stated value.

As used herein, “suitability” for removing bulk and hardened photoresist material from a microelectronic device having said photoresist material thereon, corresponds to at least partial removal of said photoresist material from the microelectronic device. Preferably, at least 90% of the photoresist material is removed from the microelectronic device using the compositions described herein, more preferably, at least 95%, and most preferably at least 99% of the photoresist material, is removed.

Compositions may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.01 weight percent, based on the total weight of the composition in which such components are employed.

In general, the compositions include at least one mineral acid and at least one sulfur-containing oxidizing agent, wherein the composition is useful for the removal of bulk and hardened photoresist from the surface of a microelectronic device.

In one aspect, a composition comprising, consisting of, or consisting essentially of at least one mineral acid and at least one sulfur-containing oxidizing agent is described, wherein the composition is useful for the removal of bulk and hardened photoresist from a microelectronic device having same thereon. In another aspect, a composition comprising, consisting of, or consisting essentially of at least one mineral acid, at least one sulfur-containing oxidizing agent, and at least one metal ion-containing catalyst is described. In general, the specific proportions and amounts of components, in relation to each other, may be suitably varied to provide the desired removal action of the composition for the bulk and hardened photoresist and/or processing equipment, as readily determinable within the skill of the art without undue effort.

Mineral acids useful for the composition of the invention include, but are not limited to, sulfuric acid, methanesulfonic acid, trifluoromethane sulfonic acid, trifluoroacetic acid, nitric acid, pyrosulfuric acid (H₂S₂O₇), pyrophosphoric acid, polymetaphosphoric acid, and combinations thereof. Most preferably, the mineral acid comprises sulfuric acid, preferably concentrated sulfuric acid, which commercially is 95% to 98% H₂SO₄. Although less favored, the sulfuric acid may be diluted such that the concentration of H₂SO₄ in the composition is in a range from about 50% to about 95%.

Sulfur-containing oxidizing agents include, but are not limited to, OXONE® (2 KHSO₅·KHSO₄·K₂SO₄), ammonium hydrogen sulfate, cesium hydrogen sulfate, potassium hydrogen sulfate, ammonium sulfate, cesium sulfate, potassium sulfate, ammonium persulfate, ammonium peroxymonosulfate, peroxymonosulfuric acid, tetrabutylammonium peroxymonosulfate, cesium peroxymonosulfate, potassium peroxymonosulfate, other peroxymonosulfate salts, other persulfate salts, and combinations thereof, with the proviso that when the mineral acid comprises sulfuric acid per se, the sulfur-containing oxidizing agent may not include peroxymonosulfuric acid (H₂SO₅). Preferably, the sulfur-containing oxidizing agent comprises OXONE®, ammonium persulfate or combinations thereof.

Metal ion-containing catalysts contemplated include, but are not limited to, ferrous salts, ferric salts, silver salts, and combinations thereof. Preferably, the metal-ion containing catalysts include ferrous sulfate (depending on solubility issues), ferrous nitrate, ferrous phosphate, ferrous perchlorate, ferrous methanesulfonate, ferrous trifluoroacetate, and combinations thereof.

Preferably, the mineral acid-containing compositions are substantially devoid of added water. It is understood that concentrated H₂SO₄ has a small amount of water, however, no additional water should be added to the compositions described herein, whether as neat water or as a diluent of component other than concentrated H₂SO₄. Accordingly, the compositions preferably include less than about 5 wt % water, based on the amount of water in the mineral acid, more preferably less than 3 wt %, and most preferably less than 2 wt %, based on the total weight of the composition. If a condensed mineral acid is used, such as pyrosulfuric or pyrophosphoric, the composition may be substantially devoid of water. Furthermore, the compositions described herein are preferably substantially devoid of abrasive material, hydrogen peroxide, non-ionic compounds having amino/CONH chains, non-ionic and other surfactants, hydroxylamine, azoles, water soluble polymers, fluoride ion-containing compounds such as SbF₅ and BF₃, imidazolium cations, pyridinium cations, pyrrolidinium cations, phosphonium cations, quaternary ammonium cations, and combinations thereof.

The amount of each component in the composition comprising, consisting of, or consisting essentially of at least one mineral acid, at least one sulfur-containing oxidizing agent, and optionally at least one metal ion-containing catalyst, based on the total weight of the composition, is:

| | Amount (wt %) |
|---|---|
| mineral acid(s) | about 75 to about 95 wt % |
| sulfur-containing oxidizing agent(s) | about 5 to about 25 wt % |
| metal ion-containing catalyst(s) | 0 to about 5 wt % |

When present, the lower amount of metal ion-containing catalyst is about 0.01 wt %. The mineral acid is the solvent in the compositions.

In a preferred embodiment, the amount of each component in the composition comprising, consisting of, or consisting essentially of at least one mineral acid, at least one sulfur-containing oxidizing agent, and optionally at least one metal ion-containing catalyst, based on the total weight of the composition, is:

| | Amount (wt %) |
|---|---|
| concentrated sulfuric acid(s) | about 75 to about 95 wt % |
| sulfur-containing oxidizing agent(s) | about 5 to about 25 wt % |
| metal ion-containing catalyst(s) | 0 to about 5 wt % |

When present, the lower amount of metal ion-containing catalyst is about 0.01 wt %.

In a particularly preferred embodiment, the composition includes concentrated H₂SO₄ and OXONE®. Preferably, the composition includes 75 wt % concentrated H₂SO₄ and 25 wt % OXONE®.

In another preferred embodiment, the amount of each component in the composition comprising, consisting of, or consisting essentially of at least one mineral acid, at least one sulfur-containing oxidizing agent, and at least one metal ion-containing catalyst, based on the total weight of the composition, is:

| | Amount (wt %) |
|---|---|
| concentrated sulfuric acid(s) | about 75 to about 95 wt % |
| sulfur-containing oxidizing agent(s) | about 5 to about 25 wt % |
| metal ion-containing catalyst(s) | about 0.01 to about 5 wt % |

In a particularly preferred embodiment, the composition includes concentrated H₂SO₄, ammonium persulfate, and at least one ferrous salt.

Importantly, the compositions described herein have pH less than about 2, more preferably less than about 1. It is to be appreciated that the pH of the compositions described herein may be less than zero, depending on the components used and the amount thereof.

In another embodiment, the aforementioned compositions described herein further include bulk and/or hardened photoresist material, wherein the bulk and/or hardened photoresist material may comprise boron, arsenic, boron difluoride, indium, antimony, germanium, and/or phosphorous ions. For example, the composition may include at least one mineral acid, at least one sulfur-containing oxidizing agent, and bulk and/or hardened photoresist material. In another embodiment, the compositions described herein may include at least one mineral acid, at least one sulfur-containing oxidizing agent, at least one metal ion-containing catalyst, and bulk and/or hardened photoresist material. In still another embodiment, the composition comprises H₂SO₄, OXONE®, and bulk and/or hardened photoresist. In yet another embodiment, the composition comprises H₂SO₄, ammonium persulfate, at least one ferrous salt, and bulk and/or hardened photoresist. Importantly, the photoresist material and implantation ions may be dissolved and/or suspended in the mineral acid-containing compositions.

The compositions are compatible with underlying silicon-containing materials on the microelectronic device.

The compositions may be readily formulated as single-package formulations or multi-part formulations that are mixed at or before the point of use, e.g., the individual parts of the multi-part formulation may be mixed at the tool, in a storage tank upstream of the tool, or in a shipping package that delivers the mixed formulation directly to the tool. For example, a single shipping package may include at least two separate containers or bladders that may be mixed together by a user at the fab and the mixed formulation may be delivered directly to the tool. One of the at least two containers or bladders may include the at least one sulfur-containing oxidizing agent, which may be a solid or a liquid, while another of the at least two containers may include at least one mineral acid and optionally at least one metal ion-containing catalyst. In one embodiment, one of the at least two containers or bladders includes the at least one sulfur-containing oxidizing agent, while a second of the at least two containers or bladders includes at least one mineral acid. In another embodiment, one of the at least two containers or bladders includes the at least one sulfur-containing oxidizing agent, while a second of the at least two containers or bladders includes a mixture of at least one mineral acid and at least one metal ion-containing catalyst. In still another embodiment, one container or bladder includes the at least one sulfur-containing oxidizing agent, a second container or bladder includes at least one mineral acid, and a third container or bladder includes at least one metal ion-containing catalyst. The shipping package and the internal containers or bladders of the package must be suitable for storing and shipping said composition components, for example, packaging provided by Advanced Technology Materials, Inc. (Danbury, Conn., USA).

Another aspect relates to a kit including, in one or more containers, one or more components adapted to form the compositions described herein. The kit may include, in one or more containers, at least one mineral acid for combining with at least one sulfur-containing oxidizing agent and at least one metal ion-containing catalyst at the fab or the point of use. Alternatively, the kit may include, in one or more containers, at least one mineral acid for combining with at least one sulfur-containing oxidizing agent at the fab or the point of use. The containers of the kit must be suitable for storing and shipping said mineral acid-containing compositions, for example, NOWPak® containers (Advanced Technology Materials, Inc., Danbury, Conn., USA). The one or more containers which contain the components of the mineral acid-containing composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended removal composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” U.S. Patent Application No. 60/916,966 entitled “SYSTEMS AND METHODS FOR MATERIAL BLENDING AND DISTRIBUTION” filed on May 9, 2007 in the name of John E. Q. Hughes, and PCT/US08/63276 entitled “SYSTEMS AND METHODS FOR MATERIAL BLENDING AND DISTRIBUTION” filed on May 9, 2008 in the name of Advanced Technology Materials, Inc.

As applied to microelectronic manufacturing operations, the compositions described herein are usefully employed to clean bulk and hardened photoresist from the surface of the microelectronic device. Importantly, the compositions do not damage low-k dielectric materials on the device surface. Preferably the compositions remove at least 85% of the bulk and hardened photoresist present on the device prior to photoresist removal, more preferably at least 90%, even more preferably at least 95%, and most preferably at least 99%.

In removal application, the mineral acid-containing composition is applied in any suitable manner to the microelectronic device having photoresist material thereon, e.g., by spraying the composition on the surface of the device, by dipping (in a volume of the composition) of the device including the photoresist material, by contacting the device with another material, e.g., a pad, or fibrous sorbent applicator element, that is saturated with the composition, by contacting the device including the photoresist material with a circulating composition, or by any other suitable means, manner or technique, by which the mineral acid-containing composition is brought into contact with the photoresist material on the microelectronic device. The application may be in a batch or single wafer apparatus, for dynamic or static cleaning.

In use of the compositions of the invention for removing bulk and hardened photoresist from microelectronic devices having same thereon, the composition typically is contacted with the device for a time of from about 10 sec to about 60 minutes, preferably about 5 min to 30 min, at temperature in a range of from about 20° C. to about 100° C., preferably about 40° C. to about 80° C. Such contacting times and temperatures are illustrative, and any other suitable time and temperature conditions may be employed that are efficacious to at least partially clean the bulk and hardened photoresist from the device, within the broad practice of the invention. “At least partially clean” and “substantial removal” both correspond to at removal of at least 85% of the and hardened photoresist present on the device prior to photoresist removal, more preferably at least 90%, even more preferably at least 95%, and most preferred at least 99%

Following the achievement of the desired removal action, the composition may be readily removed from the device to which it has previously been applied, as may be desired and efficacious in a given end use application of the compositions described herein. Preferably, the rinse solution includes cold deionized water. Alternatively, the rinse solution may include lower concentrations of mineral acid (e.g., about 10% to about 80%), whereby the device may be rinsed at or about room temperature, followed by a rinse with DI water at or about room temperature. It is to be appreciated that the device may be rinsed with multiple solutions having ever decreasing concentrations of mineral acid prior to a final rinse with DI water. Thereafter, the device may be dried using nitrogen or a spin-dry cycle.

Yet another aspect relates to the improved microelectronic devices made according to the methods described herein and to products containing such microelectronic devices.

Another aspect relates to a recycled composition, wherein the composition may be recycled until photoresist loading reaches the maximum amount the composition may accommodate, as readily determined by one skilled in the art. It should be appreciated by one skilled in the art that a filtration and/or pumping system may be needed for the recycling process.

A still further aspect relates to methods of manufacturing an article comprising a microelectronic device, said method comprising contacting the microelectronic device with a composition for sufficient time to clean bulk and hardened photoresist from the microelectronic device having said photoresist thereon, and incorporating said microelectronic device into said article, using a composition described herein.

Still another aspect relates to packaging a mineral acid-containing composition for shipping, mixing and delivery, wherein the mineral acid-containing composition includes at least one mineral acid, at least one sulfur-containing oxidizing agent, and optionally at least one metal ion-containing catalyst, said packaging comprising a external package comprising at least two internal containers or bladders, wherein a first internal container or bladder includes the at least one sulfur-containing oxidizing agent and a second internal container or bladder includes the at least one mineral acid and optionally at least one metal ion-containing catalyst, wherein the contents of the first and second internal containers or bladders may be mixed within the external package to form the mineral acid-containing composition. The formed mineral acid-containing composition may thereafter be delivered to a microelectronic device for sufficient time to remove bulk and/or hardened photoresist from the microelectronic device having said photoresist thereon.

Yet another aspect relates to a process to clean bulk and hardened photoresist from the surface of the microelectronic device using a single wafer tool (SWT) and the compositions described herein. Currently, solutions for the stripping of implanted resist are mostly used in batch mode and are based on strong oxidants, for example a sulfuric acid-hydrogen peroxide mixture (SPM). These mixtures have a limited bath life at the temperatures at which they are effective. With the present preference of SWTs over batch processing, there is a need to shorten the dissolution time of the photoresist from the typical 10-30 minutes to around 1 minute. Disadvantageously, this requires higher processing temperatures, for example about 40-80° C. higher than batch process temperatures, which speeds up the decomposition of the oxidizing agent(s) in the mineral acid-containing compositions. In SWT apparatus use, the compositions typically are contacted with the microelectronic device for a time of from about 30 sec to about 2 min, preferably about 45 sec to 90 sec, at a temperature in a range of from about 20° C. to about 190° C., preferably about 90° C. to about 140° C.

As such, higher temperature processing using SWTs is described herein. Preferably, the mineral acid-containing composition for the SWTs is a single-use composition. Embodiments include:

1. Mixing a stream of relatively cool concentrated solution of the oxidant with a hot diluent, e.g. hot sulfuric acid. Optionally, one of the solutions may contain more water than the other, to generate some heat of mixing. The mixing may be done either in a small secondary reservoir that is just large enough for the solution needed for one wafer, or by merging two tubes carrying the two different solutions together in a “Y” connection;
2. Heating the oxidizing solution from outside the tubing while en route to the device wafer; and/or
3. Positioning the device wafer on a metal chuck with high thermal mass and controllable temperature, and relying on the heat conductivity of the wafer to quickly heat up the mineral-acid containing composition by a few tens of degrees.

The features and advantages are more fully shown by the illustrative examples discussed below.

### Example 1

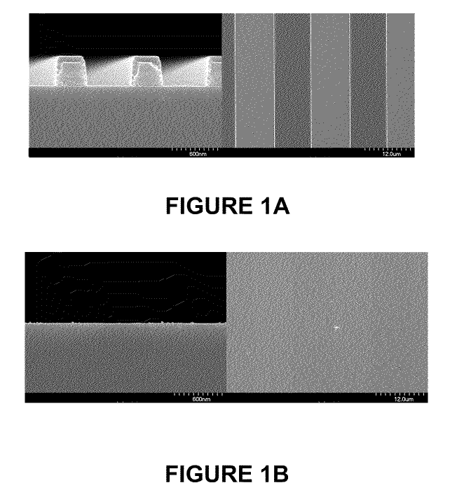

A patterned wafer having photoresist lines on an oxide layer, wherein the photoresist was doped with 2.1×10¹⁵ atoms cm⁻² boron at with 35 KeV of energy, was immersed in a composition described herein including 75 wt % concentrated H₂SO₄ (95-98%) and 25 wt % OXONE® for 30 minutes at 80° C. As can be seen in FIG. 1, wherein FIG. 1A represents the wafer prior to immersion and FIG. 1B represents the wafer subsequent to immersion, the bulk and hardened photoresist was substantially removed from the surface of the wafer. Importantly, the underlying oxide layer was not substantially etched.

### Example 2

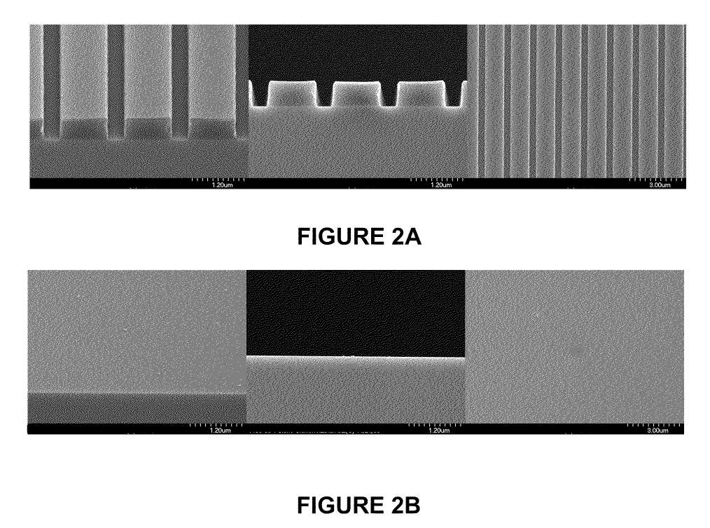

A patterned wafer having photoresist lines on an oxide layer, wherein the photoresist was doped with 2×10¹⁵ atoms cm⁻² arsenic at with 20 KeV of energy, was immersed in a composition described herein including 75 wt % concentrated H₂SO₄ (95-98%) and 25 wt % OXONE® for 10 minutes at 80° C. As can be seen in FIG. 2, wherein FIG. 2A represents the wafer prior to immersion and FIG. 2B represents the wafer subsequent to immersion, the bulk and hardened photoresist was substantially removed from the surface of the wafer. Importantly, the underlying oxide layer was not substantially etched.

### Example 3

A patterned wafer having photoresist lines on an oxide layer, wherein the photoresist was doped with 2×10¹⁵ atoms cm⁻² arsenic at with 20 KeV of energy, was immersed in a composition described herein including 75 wt % concentrated H₂SO₄ (95-98%) and 25 wt % ammonium persulfate for 30 minutes at 80° C. The bulk and hardened photoresist was substantially removed from the surface of the wafer. Importantly, the underlying oxide layer was not substantially etched.

Importantly, when ferrous salts are added to the composition including concentrated H₂SO₄ and ammonium persulfate, the bulk and hardened photoresist may be removed using milder conditions, such as temperature in a range from about 40° C. to about 60° C.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

1. A mineral acid-containing composition comprising at least one mineral acid and at least one sulfur-containing oxidizing agent.

2. The composition of claim 1, further comprising at least one metal ion-containing catalyst.

3. (canceled)

4. The composition of claim 1, wherein the at least one mineral acid comprises an acid selected from the group consisting of sulfuric acid, methanesulfonic acid, trifluoromethane sulfonic acid, trifluoroacetic acid, nitric acid, pyrosulfuric acid (H₂S₂O₇), pyrophosphoric acid, polymetaphosphoric acid, and combinations thereof.

5. The composition of claim 1, wherein the at least one mineral acid comprises sulfuric acid.

6. The composition of claim 1, wherein the at least one sulfur-containing oxidizing agent comprises a species selected from the group consisting of OXONE®, ammonium hydrogen sulfate, cesium hydrogen sulfate, potassium hydrogen sulfate, ammonium sulfate, cesium sulfate, potassium sulfate, ammonium persulfate, ammonium peroxymonosulfate, potassium peroxymonosulfate, peroxymonosulfuric acid, tetrabutylammonium peroxymonosulfate, cesium peroxymonosulfate, other peroxymonosulfate salts, other persulfate salts, and combinations thereof.

7. The composition of claim 1, wherein the at least one sulfur-containing oxidizing agent comprises OXONE®.

8. The composition of claim 2, wherein the at least one metal ion-containing catalyst comprises a salt selected from the group consisting of a ferrous salt, a ferric salt, a silver salt, and combinations thereof.

9. The composition of claim 2, wherein the at least one metal ion-containing catalyst comprises a ferrous salt.

10. The composition of claim 1, wherein the pH is less than 2.

11. The composition of claim 1, wherein the composition further comprises bulk and/or hardened photoresist material residue, wherein the photoresist material residue comprises at least one implanted ion selected from the group consisting of B, As, P, BF₂, In, Ge, Sb, and combinations thereof.

12-14. (canceled)

15. The composition of claim 1, wherein the composition comprises less than about 5 wt % water, based on the total weight of the composition.

16. The composition of claim 1, wherein the composition is substantially devoid of abrasive material, hydrogen peroxide, non-ionic compounds having amino/CONH chains, non-ionic and other surfactants, hydroxylamine, azoles, water soluble polymers, fluoride ion-containing compounds, imidazolium cations, pyridinium cations, pyrrolidinium cations, phosphonium cations, quaternary ammonium cations, and combinations thereof.

17. A kit comprising a package, wherein said package comprises at least two internal containers, wherein a first internal container includes at least one sulfur-containing oxidizing agent and a second internal container includes at least one mineral acid and optionally at least one metal ion-containing catalyst, wherein the contents of the first and second internal containers may be mixed within the package to form a mineral acid-containing composition.

18. A method of removing bulk and/or hardened photoresist material from a microelectronic device having said photoresist material thereon, said method comprising contacting the microelectronic device with a mineral acid-containing composition for sufficient time and under sufficient contacting conditions to at least partially remove said photoresist material from the microelectronic device, wherein the mineral acid-containing composition comprises at least one mineral acid and at least one sulfur-containing oxidizing agent.

19. The method of claim 18, wherein the composition further comprises at least one metal ion-containing catalyst.

20. (canceled)

21. (canceled)

22. The method of claim 18, wherein the bulk and/or hardened photoresist materials comprise dopant ions selected from the group consisting of arsenic ions, boron ions, phosphorous ions, indium ions, antimony ions, boron difluoride, germanium, and combinations thereof.

23. (canceled)

24. The method of claim 18, further comprising rinsing the microelectronic device following contact with the mineral acid-containing composition.

25. The method of claim 24, wherein said rinsing comprises contacting the microelectronic device with deionized water or dilute sulfuric acid.

26. (canceled)

27. The method of claim 18, wherein said contacting comprises mixing a stream of the at least one sulfur-containing oxidizing agent at a first temperature with a stream of the at least one mineral acid at a second temperature, wherein the first temperature is lower than the second temperature.

28. The method of claim 27, wherein at the first temperature is in a range from about 20° C. to about 40° C. and the second temperature is in a range from about 90° C. to about 140° C.
